(19) United States
(12) Patent Application Publication
(10) Pub. No.: US 2011/0140078 A1
(43) Pub. Date: Jun. 16, 2011

(54) LIGHT-EMITTING DEVICE AND METHOD OF MAKING THE SAME

(76) Inventor: Chia Liang HSU, (US)

(21) Appl. No.: 12/969,001

(22) Filed: Dec. 15, 2010

(30) Foreign Application Priority Data
Dec. 16, 2009 (TW) 098143295

(51) Int. Cl. H01L 33/06; H01L 33/00

(52) U.S. Cl. 257/13; 438/28; 257/E33.068; 257/E33.001

(57) ABSTRACT

This disclosure discloses a light-emitting device. The light-emitting device comprises a light-emitting diode chip comprising a plurality of light-emitting diode units and at least one electrical connecting layer. The light-emitting diode units are electrically connected with each other through the electrical connecting layer. Each of the light-emitting diode units comprises a first semiconductor layer, a second semiconductor layer, and an active layer. The light-emitting device further comprises a bonding layer; and a carrier bonded to the light-emitting diode chip by the bonding layer. The electrical connecting layer is formed between the light-emitting diode units and the bonding layer.

### REFERENCE TO RELATED APPLICATION

This application claims the right of priority based on TW application Ser. No. 098143295, filed Dec. 16, 2009, and the content of which is hereby incorporated by reference.

### BACKGROUND

1. Technical Field

The present disclosure relates to a light-emitting device and a method of making the same.

2. Description of the Related Art

Recently, as the epitaxial and manufacturing technology develops, light-emitting diodes (LEDs) which are one of the solid-state lighting elements have great progress in the light efficiency. Based on physical mechanism, the LEDs are driven by direct current. Therefore, additional electrical devices such as rectifier or adapter are required for inverting alternating current to direct current which is supplied to the LEDs for lighting. However, since the electrical devices have large volume and heavy weight, the cost is increased and the power is loss during inverting, thereby adversely affecting the reliability and the life-time of the LEDs.

An alternating current light-emitting device (ACLED) does not include the electrical devices and can be directly driven by alternating current. So far, the ACLED comprises two structures. One is the light-emitting diodes electrically connected in anti-parallel connection, and the other is the light-emitting diodes electrically connected to form a Wheatstone bridge circuit which comprises a first circuit as a bridge rectifier and a second circuit. During operation, half of the light-emitting diodes are lightened when the light-emitting diodes electrically are connected in anti-parallel connection, whereas half of the light-emitting diodes in the first circuit and the light-emitting diodes in the second circuit are lightened when the light-emitting diodes are electrically connected to form the Wheatstone bridge circuit. Therefore, the light-emitting diodes which are electrically connected to form the Wheatstone bridge circuit have improved light-emitting area for enhancing light-emitting efficiency.

FIG. 1 shows a conventional alternating current light-emitting device. The light-emitting device comprises electrodes 32 as an electrical connection layer, and portions of light-emitting regions 31 of the light-emitting device are shielded by the electrical connection layer, thereby reducing light output efficiency.

### SUMMARY OF THE DISCLOSURE

The present disclosure provides a light-emitting device.

The light-emitting device comprises a plurality of light-emitting diode units and at least one electrical connecting layer. The light-emitting diode units are electrically connected with each other through the electrical connecting layer. Each of the light-emitting diode units comprises a first semiconductor layer, a second semiconductor layer, and an active layer. The light-emitting device further comprises a bonding layer; and a carrier bonded to the light-emitting diode chip by the bonding layer. The electrical connecting layer is formed between the light-emitting diode units and the bonding layer.

In another embodiment of the present disclosure, a light light-emitting device is provided. The light-emitting device comprises: a light-emitting diode chip comprising a plurality of light-emitting diode units, at least two electrodes, and at least one electrical connecting structure. The light-emitting diode units are electrically connected with each other by the electrical connecting structure. Each of the light-emitting diode units comprises a first semiconductor layer, a second semiconductor layer and an active layer. The light-emitting device further comprises a substrate and a plurality of external electrodes. The light-emitting diode chip is formed on one side of the substrate and the external electrode is formed on another side of the substrate.

In another embodiment of the present disclosure, a light light-emitting device is provided. The light-emitting device comprises: a light-emitting diode chip comprising a plurality of light-emitting diode units, and at least one electrical connecting structure. The light-emitting diode units are electrically connected with each other by the electrical connecting structure. Each of the light-emitting diode units comprises a first semiconductor layer, a second semiconductor layer and an active layer. The light-emitting diode device further comprises a sub-mount that comprises at least one conductive layer disposed thereon. The light-emitting diode chip is bonded to and electrically connected to the sub-mount by the conductive layer.

This present disclosure also provides a method of making a light-emitting device. The method comprises forming a light-emitting diode chip on a substrate wherein the light-emitting diode chip comprising a plurality of light-emitting diode units and a plurality of electrodes; forming an insulation structure between the light-emitting diode units; forming an electrical connection structure in the insulation structure for electrically connecting the light-emitting diode units; applying an insulating layer to the electrical connection structure; forming a plurality of channels in the substrate; forming a conductive material within the channels for electrically connecting to the electrodes of the light-emitting diode chip; and forming a plurality of external electrodes on the substrate for electrically connecting to the electrodes.

### BRIEF DESCRIPTION OF THE DRAWINGS

The accompanying drawings are included to provide easy understanding of the application, and are incorporated herein and constitute a part of this specification. The drawings illustrate the embodiment of the application and, together with the description, serve to illustrate the principles of the application.

FIG. 1 shows a view of a conventional alternating current light-emitting device.

FIG. 2 shows a cross-sectional view of a light-emitting device in accordance with one embodiment of the present disclosure.

FIGS. 3A to 3G shows cross-sectional views of making the light-emitting device illustrated in FIG. 2.

FIG. 4 shows a cross-sectional view of a light-emitting device in accordance with another embodiment of the present disclosure.

FIG. 5 shows a cross-sectional view of a light-emitting device in accordance with another embodiment of the present disclosure.

FIG. 6 shows a cross-sectional view of another embodiment of the light-emitting device illustrated in FIG. 5.

FIG. 7A shows a top view of a light-emitting device in accordance with another embodiment of the present disclosure.

FIG. 7B shows a cross-sectional view of the light-emitting device, taken along line A-A′-A″ of FIG. 7A.

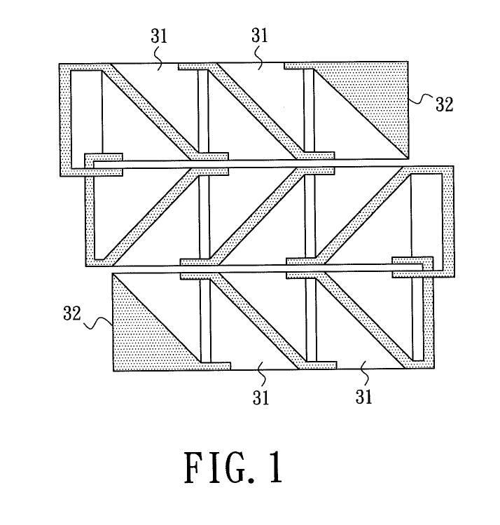

### DETAILED DESCRIPTION OF THE EMBODIMENTS

For to better and concisely explain the disclosure, the same name or the same reference number given or appeared in different paragraphs or figures along the specification should has the same or equivalent meanings while it is once defined anywhere of the disclosure.

The following shows the description of the embodiments of the present disclosure in accordance with the drawings.

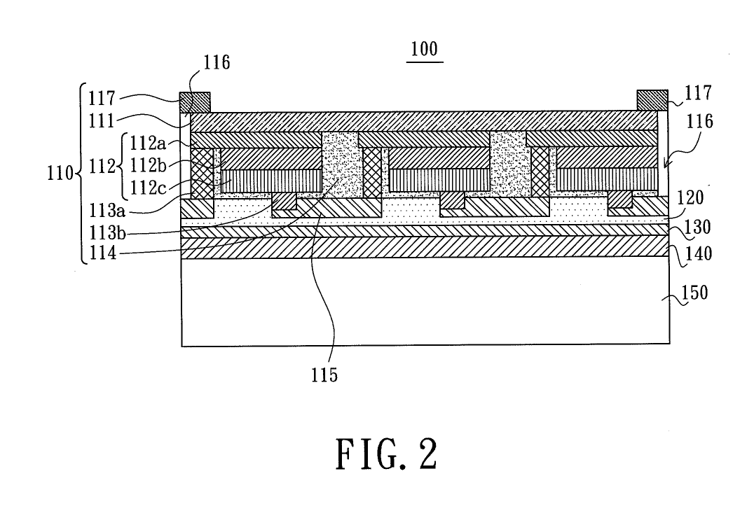

As shown in FIG. 2, the light-emitting device 100 comprises a light-emitting diode chip 110, an insulating layer 120, a reflective layer 130, a bonding layer 140, and a permanent substrate 150.

The insulating layer 120 is formed on the light-emitting diode chip 110. The reflective layer 130 is formed on the insulating layer 120 opposite to the light-emitting diode chip 110 for reflecting the light generating from the light-emitting diode chip 110 so as to improve the light extraction efficiency of the light-emitting device 100. The bonding layer 140 is formed on the reflective layer 130 opposite to the light-emitting diode chip 110 and is used for bonding the permanent substrate 150 to the light-emitting diode chip 110. By virtue of the insulating layer 120, the electrical connection between the light-emitting diode chip 110 and the reflective layer 130, and the bonding layer 140 and the permanent substrate 150 can be prevented. In this embodiment, the permanent substrate 150, for example, is a Si substrate.

The light-emitting diode chip 110 comprises a growth substrate 111, a plurality of light-emitting diode units 112, an insulation structure 114, an electrical connecting structure 115, channels 116, and external electrodes 117. The light-emitting diode units 112 are grown on the growth substrate 111, for example, by metal organic chemical vapor deposition (MOCVD). In this embodiment, each of the light-emitting diode units 112 comprises an n-type semiconductor layer 112a, an active layer 112b, and a p-type semiconductor layer 112c which are sequentially formed on the growth substrate 111. The active layer 112b comprises a multiple quantum well structure. A buffer layer can be formed between the n-type semiconductor layer 112a and the growth substrate 111 by ion implantation and other methods. Furthermore, a current spreading layer (not shown) can be formed on the p-type semiconductor layer 112c opposite to the active layer 112b for uniformly spreading current. Each of the light-emitting diode units 112 further comprises a first electrode 113a and a second electrode 113b. The first electrode 113a is an n-type electrode and is disposed on the n-type semiconductor layer 112a, and the second electrode 113b is a p-type electrode and is disposed on the p-type semiconductor layer 112c. Preferably, the first and second electrodes 113a, 113b are in ohmic contact with the n-type semiconductor layer 112a and the p-type semiconductor layer 112c, respectively. The insulation structure 114 is formed between any two adjacent light-emitting diode units 112. In this embodiment, a width of the insulation structure 114 is required to be large enough for preventing electrical connection which is not provided by the electrical connecting structure 115, thereby obtaining an effective insulation. By virtue of the insulation structure 114, the light-emitting diode units 112, especially the active layer 112b, are protected from damage resulting from electrostatic discharge and short-circuit. In this embodiment, the insulation structure 114 is locally planarized by a spin-on-glass process.

The electrical connection structure 115 is formed on the insulation structure 114, and electrically connects the first electrode 113a of one of the light-emitting diode units 112 and the second electrode 113b of another of the light-emitting diode units 112. By virtue of the electrical connection structure 115, the light-emitting diode units 112 of the light-emitting diode chip 110 can be connected in series or in parallel with each other. The electrical connection between the light-emitting diode units 112 comprises series, parallel, series-parallel or anti-parallel configurations. Moreover, the light-emitting diode units 112 serially connected with each other can form a multiple-dies chip (MC) comprising the light-emitting diode units 12. For operating in various voltages, a single diode chip structure or a combined structure comprising a plurality of the single diode chip structures can be provided to couple to a direct current power source or a rectified alternating current (AC) power source. Alternatively, a single diode chip structure comprising the light-emitting diode units 112 which form a Wheatstone bridge configuration can be coupled to an AC power source. In this embodiment, since the light-emitting diode units 112 are electrically connected with each other by the electrical connection structure 115, when only two electrodes (the first electrode 113a of one of the light-emitting diode units 112 and the second electrode 113b of another of the light-emitting diode units 112) are coupled to a power source, an operating voltage from the power source can be supplied to each of the light-emitting diode units 112 of the light-emitting diode chip 110.

In this embodiment, the growth substrate 111 is a sapphire substrate and has a thickness of about 10 μm after polishing. The growth substrate 111 comprises two channels 116 penetrating directly and indirectly through the growth substrate 111. It is herein noted that “directly through” means the channels 116 extend in straight-line fashion and the “indirectly through” means the channels 116 extend in nonlinear or curved fashion. The channels 116 are formed in the growth substrate 111 and a conductive material is filled in the channels 116. The external electrodes 117 are formed on the growth substrate 111 at positions corresponding to the channels 116 and electrically connecting with the light-emitting diode units 112 through the conductive material. Specifically, the external electrodes 117 are electrically connected with the first electrode 113a of one of the light-emitting diode units 112 and the second electrode 113b of another of the light-emitting diode units 112 through the conductive material within in the channels 116. It is worth mentioning that when the electrical connection structure 115 is provided for electrical connections between the light-emitting diode units 112, the first and second electrodes 113a, 113b are not required to be formed on each of the light-emitting diode units 112 and only two electrodes (the first electrode 113a of one of the light-emitting diode units 112 and the second electrode 113b of another of the light-emitting diode units 112) are formed at position corresponding to the external electrodes 117 for electrical connection. Consequently, manufacturing process can be reduced and reliability of the light-emitting diode chip 110 can be enhanced.

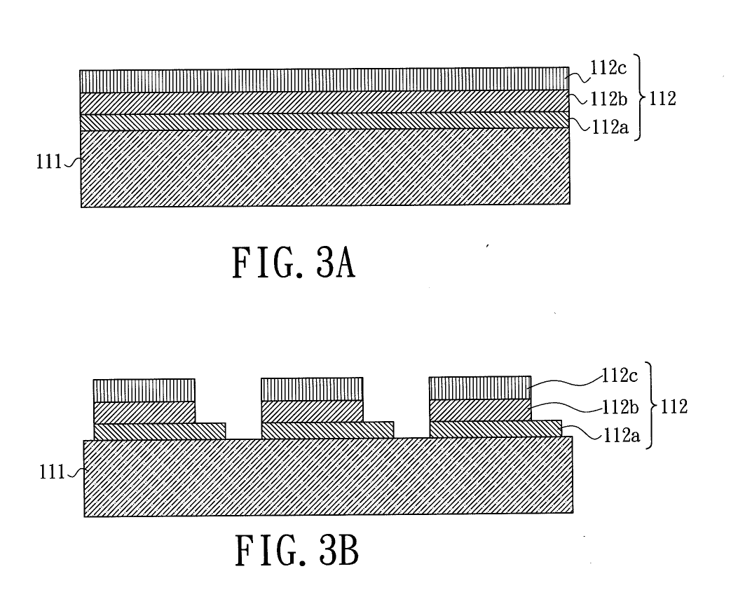

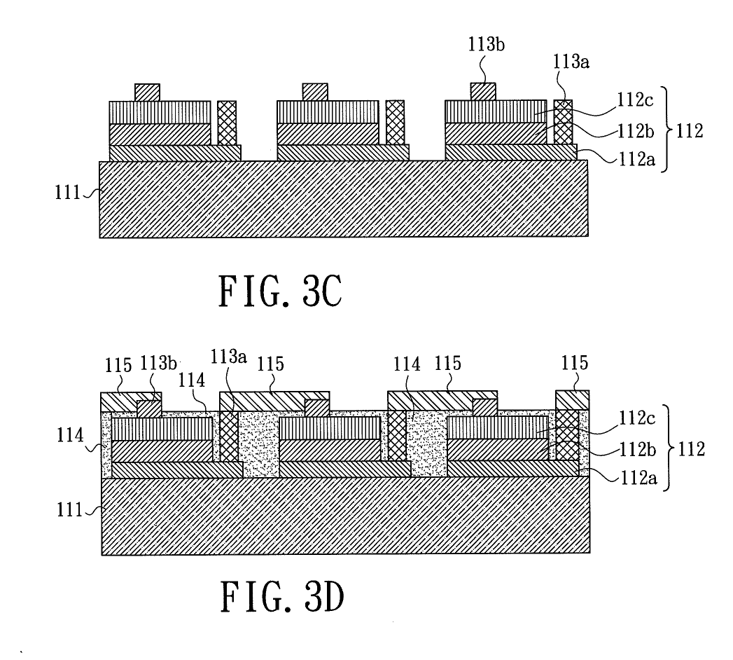

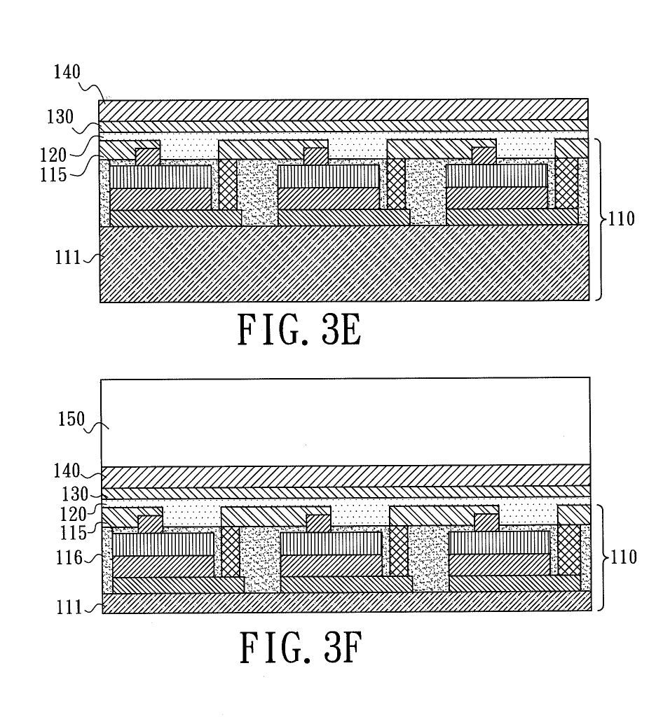

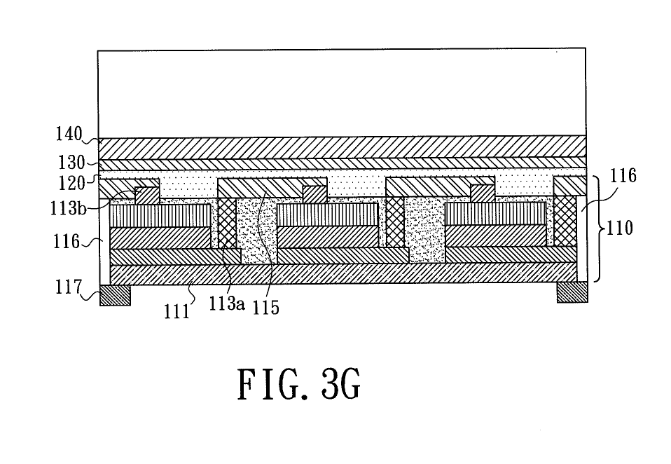

FIGS. 3A to 3G show a method of making the light-emitting device 100 in accordance to one embodiment of this present disclosure. In FIG. 3A, the n-type semiconductor layer 112a, the active layer 112b and the p-type semiconductor layer 112c are in order formed on the growth substrate 111. As shown in FIG. 3B, parts of the n-type semiconductor layer 112a, the active layer 112b and the p-type semiconductor layer 112c are removed to form a plurality of spaced-apart epitaxial structures and to expose portion of the growth substrate 111. In addition, parts of the active layer 112b and the p-type semiconductor layer 112c in each epitaxial structure are removed to expose portion of the n-type semiconductor layer 112a. As shown in FIG. 3C, in each epitaxial structure, the first electrode 113a is formed on the exposed portion of the n-type semiconductor layer 112a, and the p-type electrode 113b is formed on the p-type semiconductor layer 112c. As shown in FIG. 3D, the insulation structure 114 is formed between two adjacent light-emitting diode units 112. The insulation structure 114 can be formed along a sidewall of the light-emitting diode units 112 or covers a surface of the p-type semiconductor layer 112c. Moreover, the insulation structure 114 can further covers the exposed portion of the growth substrate 111. Subsequently, the electrical connecting structure 115 is formed such that the light-emitting diode units 112 are electrically connected with each other. Specifically, the first electrode 113a of one of the light-emitting diode units 112 is electrically connected to the second electrode 113b of adjacent light-emitting diode unit 112 through the electrical connecting structure 115. Alternatively, each of the light-emitting diode units 112 does not have the first and second electrodes formed thereon, and the electrical connecting structure 115 is provided to serially or parallelly connect the light-emitting diode units 112 to form the light-emitting diode chip 110 which comprises the light-emitting diode units 112 in series, parallel, series-parallel or anti-parallel connection. Moreover, the light-emitting diode units 112 serially connected with each other can form a single diode chip. For operating in various voltages, a single diode chip structure or a combined structure comprising a plurality of the single diode chip structures can be provided to couple to a direct current power source or a rectified alternating current (AC) power source. Alternatively, a single diode chip structure comprising the light-emitting diode units 112 which form a Wheatstone bridge configuration can be coupled to an AC power source. The electrical connecting structure 115 is partially or completely formed on the insulation structure 114. The insulation structure 114 is provided for insulating the electrical connection which is not provided by the electrical connecting structure 115, thereby obtaining an effective insulation to prevent the light-emitting diode units 112 from damage. As shown in FIG. 3E, the insulating layer 120 is coated on the electrical connecting structure 115. The reflective layer 130 is formed on the insulating layer 120 opposite to the light-emitting diode chip 110 for reflecting light emitted from the light-emitting diode chip 110. Alternatively, the reflective layer 130 can comprise multiple layers for each having different refractive index, such as Bragg reflective layer. The bonding layer 140, such as a wafer bonding layer or a metal bonding layer, is formed on the reflective layer 130 opposite to the insulating layer 120. As shown in FIG. 3F, the permanent substrate 150 is bonded to the light-emitting diode chip 110 by the bonding layer 140. In this embodiment, bonding the permanent substrate 150 to the bonding layer 140 is conducted by a wafer bonding method. Hereafter, the growth substrate 11 is polished to a remaining thickness of 10 μm. As shown in FIG. 3G, the growth substrate 111 is subject to an etching treatment to form the channels 116 directly or indirectly penetrating thought the growth substrate 111. The channels 116 are filled with the conductive material for electrically connecting the electrodes (113a and 113b) of the light-emitting diode chip 110 to a side of the growth substrate 111. The external electrodes 117 are formed on the side of the growth substrate 111 at positions corresponding to the channels 116.

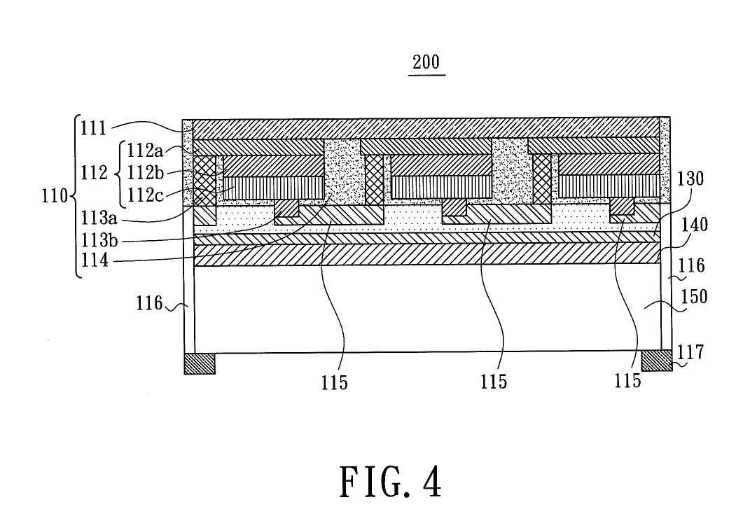

FIG. 4 shows a cross-sectional view of a light-emitting device 200 in accordance with another embodiment of the present disclosure. In this embodiment, the permanent substrate 150 is an aluminum nitride (AIN) substrate, and the channels 116 are formed to directly penetrate through the permanent substrate 150. The external electrodes 117 are formed on the permanent substrate 150 at positions corresponding to the channels 116.

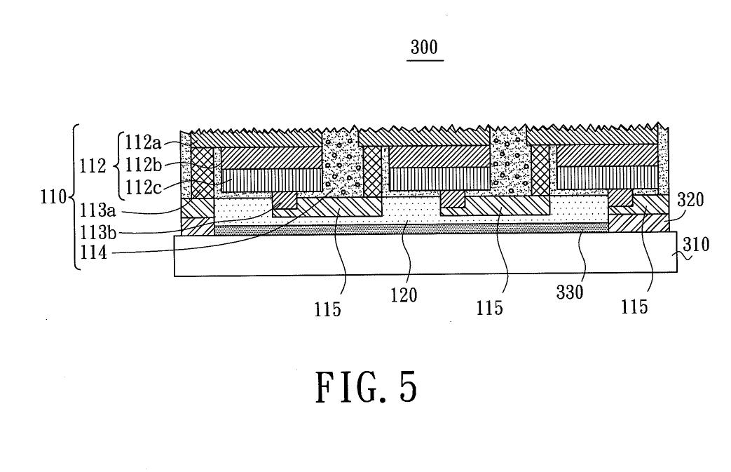

FIG. 5 shows a cross-sectional view of a light-emitting device 300 in accordance with another embodiment of the present disclosure. The light-emitting device 300 comprises the light-emitting diode chip 110, a sub-mount 310 and at least one conductive layer 320. The sub-mount 310 comprises a circuit. The conductive layer 320 is formed on the sub-mount 310 or further on the light-emitting diode chip 110. By virtue of the conductive layer 320, the light-emitting diode chip 110 is adhered to and/or mounted on the sub-mount 310, thereby forming electrical connection therebetween. In addition, the conductive layer 320 can be connected to the external electrodes 117 (not shown). The electrical connection between the light-emitting diode chip 110 and the sub-mount 310 is conducted by soldering process or adhesive process. In the soldering process, the conductive layer 320 is alloy solder bump or metal solder bump. When the conductive layer 320 on the sub-mount 310 and on the light-emitting diode chip 110 is made of a single metal, a eutectic soldering is carried out to from the alloy solder bump. The conductive layer 320 can be an isotropic conductive adhesive (ICA). In the adhesive process, the conductive layer 320 is an anisotropic conductive adhesive (ACA) applied as a film or a paste. Under heat and pressure, the adhesive is cured for adhering the light-emitting diode chip 110 to the sub-mount 310. The sub-mount 310 comprises a lead frame, a mounting substrate or a circuit board (such as printed circuit board) for achieving circuit design goals and improving heat-dissipating efficiency of the light-emitting device 300. In this embodiment, the growth substrate 111 is removed from the light-emitting diode chip 110. A heat conductive structure 330 is formed or filled between the light-emitting diode chip 110 and the sub-mount 310 for improving heat-dissipating efficiency of the light-emitting diode chip 110. After removal of the growth substrate 111, a roughing step is performed such that the light-emitting diode chip 110 having a roughed surface or a roughed structure is obtained for increasing the light extraction efficiency of the light-emitting diode chip 110. Phosphor material and scattering particles can be included in the insulation structure 114. The light emitted from the light-emitting diode units 112 is converted by the phosphor material and is mixed to form a mixed light. The wavelength of the converted light is larger than the light emitted from the light-emitting diode units 112. For example, the blue light is converted to the red light and the yellow light to form a white light or other color light. The light emitted from the light-emitting diode units 112 into the insulation structure 114 is scattered by the scattering particles for increasing light output efficiency. Scattering particles are made of a material selected from the group consisting of titanium oxide (TiO₂), silicon oxide (SiO₂), and combinations thereof. The phosphor material and/or the scattering particles can be included in the insulation structure 114 to form the insulation structure 114 comprising the phosphor material and/or the scattering particles. Depending on actual requirement, compositions and concentrations of the phosphor material or scattering particles in the insulation structure 114 can be adjusted.

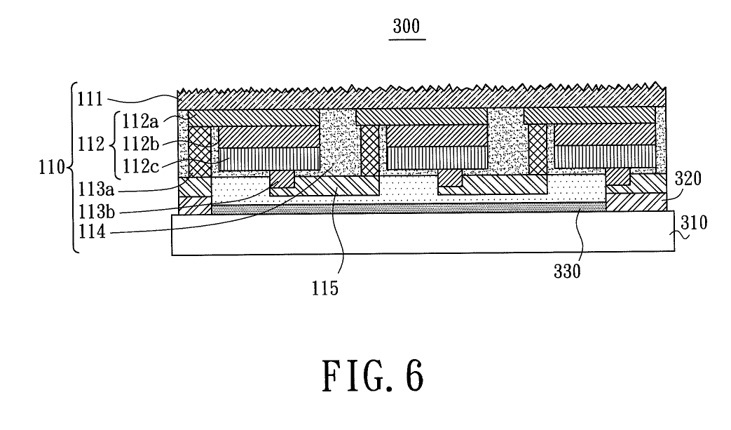

Referring to FIG. 6, the growth substrate 111 of the light-emitting device 300 is not removed and is subject to surface roughing treatment to have a roughed surface or a roughed structure for increasing the light extraction efficiency of the light-emitting device 300. The insulation structure 114 shown in FIG. 6 can have the phosphor material and/or the scattering particles included therein.

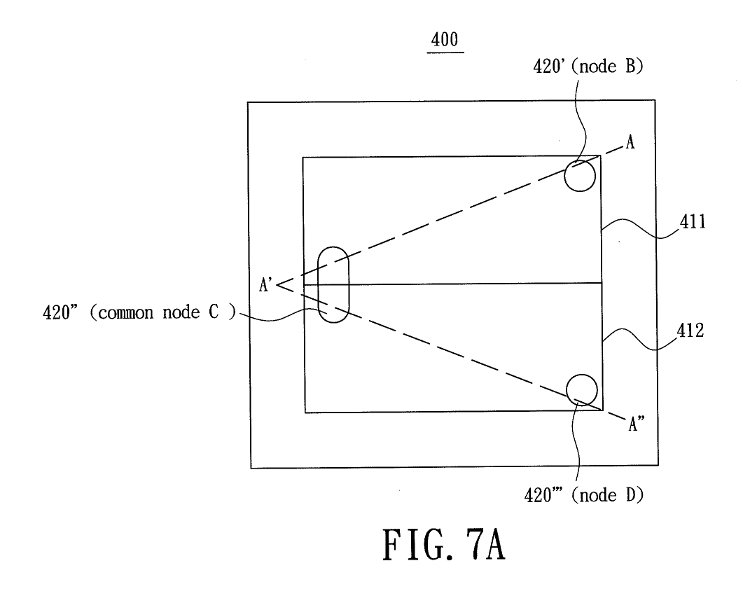

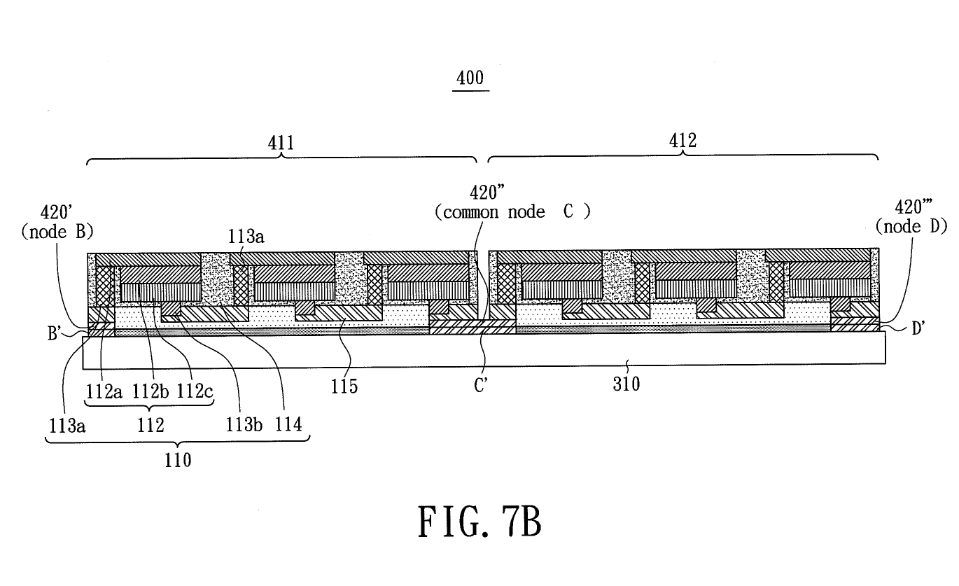

FIGS. 7A and 7B show views of a light-emitting device 400 in accordance with another embodiment of the present disclosure. FIG. 7A is a top view of the light-emitting device 400 and FIG. 7B is a cross-sectional structure across the cross-section line A-A′-A″ of FIG. 7A. In this embodiment, there are at least three electrical contacts formed between the light-emitting diode chip 110 and the sub-mount 310. The light-emitting diode chip 110 comprises two light-emitting groups 411, 412. Each of the two light-emitting groups 411, 412 comprises the light-emitting diode units 112 connected in series with each other. For example, the two light-emitting groups 411, 412 are operable at a voltage having a root mean square value of 120V or 240V or, at a voltage having a peak value or a root mean square value of 33V or 72V. Each of the light-emitting groups 411, 412 can have at least two electrical contacts formed thereon. Alternatively, the light-emitting groups 411, 412 can have a common electrical contact. When the light-emitting groups 411, 412 has at least two electrical contacts, one of the two electrical contacts in each light-emitting group 411, 412 are electrically connected to each other to form a common electrical contact 420″ (common node C) such that a signal can be supplied to the light-emitting groups 411, 412 through the second electrical contact 420″. In addition, other electrical functions provided by the common node can also be obtained. The light-emitting group 411 has an electrical contact 420′ (node B) other than the common node C and the light-emitting group 412 has an electrical contact 420′″ (node D) other than the common node C. In this embodiment, the electrical contacts 420′, 420″, 420′″ are made of a material as same as that of the conductive layer 320. The conductive layer 320 formed on the sub-mount 310 serves as three connections (node B′, C′, and D′) at positions corresponding to the electrical contacts 420′, 420″, 420′″ (nodes B, C, and D). Therefore, when a power source is coupled to the connections (nodes B′, C′, and D′), a signal from the power source can be supplied to the light-emitting groups 411, 412 through the electrical contacts (nodes B, C, and D). When two electrodes (not shown) of the power source are coupled to the connections (nodes B′, and D′), respectively, such that the light-emitting groups 411, 412 are electrically connected in series with each other. On the contrary, when one of the two electrodes of the power source is coupled to the connections (nodes B′, and D′), and the other of the two electrodes of the power source is coupled to the connection (node C′) such that the light-emitting groups 411, 412 are electrically connected in anti-parallel with each other. Therefore, various electrical connections between the light-emitting groups 411, 412 can be achieved. For example, when a power source providing a voltage having a root mean square value of 120V is coupled to the light-emitting device 400, the anti-parallel connection, packages, and wire bonding of the light-emitting device 400 can be carried out. When the power source providing a voltage having a root mean square value of 240V is coupled to the light-emitting device 400, the series connection, packages, and wire bonding of the light-emitting device 400 can be carried out. Therefore, using the same light-emitting device 400, various electrical connections can be achieved. In addition, since the sub-mount is provided for electrically connecting to the power source, the light-emitting device 400 has increased reliability. It is noted that, each of the light-emitting groups 411, 412 can be a light-emitting diode chip 110.

The light-emitting device of the present disclosure can be a flip-chip package structure having light emitted toward the substrate. Since light emitted toward the substrate, conductive structures within the light-emitting diode chip, such as the electrodes or the electrical connecting structure, are not transparent. Moreover, there is no need to reduce the area and/or shape of the conductive structure or to change any process of making the electrical structure, thereby enhancing light-emitting efficiency and reducing manufacturing cost.

Furthermore, the light-emitting device of the present disclosure can be packaged by a conventional package method or a wafer-level package method. When the light-emitting device is packaged by the wafer-level package method, the electrical elements within the package have the same size scale. Subsequently, a single or a plurality of the light-emitting devices can be packed to a package support, thereby simplifying packages steps such as wire bonding, for reducing package cost and increasing package reliability.

Each of the n-type semiconductor layer 112a, the active layer 112b, and the p-type semiconductor layer 112c comprises group III-V compound semiconductor, such as GaN based material or GaP based material. The growth substrate 111 comprises a material selected from the group consisting of sapphire, silicon carbide, gallium nitride, gallium aluminum, and combinations thereof. Each of the n-type semiconductor layer 112a, the active layer 112b, and the p-type semiconductor layer 112c comprising the group III-V compound semiconductor can be a single structure or a multilayer structure, such as a superlattice structure. In addition, the light-emitting diode chip of the present disclosure is directly or indirectly bonded to an electrically and thermally conductive substrate, but the light-emitting diode chip can be grown on the electrically and thermally conductive substrate.

The current spreading layer comprises metal, metal alloy, and transparent metal oxide such that indium tin oxide (ITO), and combinations thereof. The permanent substrate comprises transparent substrate or thermal conductive substrate. The transparent substrate comprises gallium phosphorus, sapphire, silicon carbide, gallium nitride, aluminum nitride, and combinations thereof. The thermal conductive substrate comprises diamond, diamond-like carbon (DLC), zinc oxide, gold, silver, aluminum, and combinations thereof. The bonding layer comprises metal oxides, non-metal oxides, polymer, metal, metal alloy, and combinations thereof.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device comprising:
a light-emitting diode chip comprising a plurality of light-emitting diode units and at least one electrical connecting layer, the light-emitting diode units being electrically connected with each other through the electrical connecting layer, each of the light-emitting diode units comprising a first semiconductor layer, a second semiconductor layer, and an active layer;
a bonding layer; and
a carrier bonded to the light-emitting diode chip by the bonding layer;
wherein the electrical connecting layer is formed between the light-emitting diode units and the bonding layer.

2. The light-emitting device of claim 1, wherein the light-emitting diode chip further comprises an insulation structure formed between the light-emitting diode units wherein the insulation structure comprises scattering particles, phosphor materials, and/or combinations thereof.

3. The light-emitting device of claim 2, wherein the light-emitting diode units emit a first visible light having a first wavelength, and parts of the first visible light is converted by the phosphor materials in the insulation structure to a second visible light having a second wavelength, and wherein the second wavelength is greater than the first wavelength.

4. The light-emitting device of claim 1, wherein the light-emitting diode units comprise two light-emitting diode groups, and the light-emitting diode groups comprise at least a common node.

5. The light-emitting device of claim 4, wherein electrical connection between the light-emitting diode groups via the common node is selected from the group consisting of series connection, parallel connection, series-parallel connection, anti-parallel connection, and bridge connection, and combinations thereof.

6. The light-emitting device of claim 1, further comprising a reflective layer disposed between the light-emitting diode chip and the bonding layer.

7. The light-emitting device of claim 1, wherein the light-emitting diode chip further comprises a plurality of electrodes through which electricity is provided to the light-emitting diode units.

8. The light-emitting device of claim 7, further comprising a plurality of external electrodes electrically connected to the light-emitting diode chip.

9. The light-emitting device of claim 8, wherein the light-emitting diode chip comprises a plurality of channels wherein the external electrodes being electrically connected to the electrodes of the light-emitting diode chip through the channels.

10. The light-emitting device of claim 9, wherein the light-emitting diode chip further comprises a growth substrate, the light-emitting diode units being formed on one side of the growth substrate and the external electrode being formed on another side of the growth substrate.

11. The light-emitting device of claim 1, wherein the light-emitting diode chip has the same size scale as the carrier.

12. A light-emitting device comprising:
a light-emitting diode chip comprising a plurality of light-emitting diode units, at least two electrodes, and at least one electrical connecting structure, the light-emitting diode units being electrically connected with each other by the electrical connecting structure, each of the light-emitting diode units comprising a first semiconductor layer, a second semiconductor layer and an active layer;
a substrate; and
a plurality of external electrodes;
wherein the light-emitting diode chip is formed on one side of the substrate and the external electrode is formed on another side of the substrate.

13. The light-emitting device of claim 12, wherein the light-emitting diode chip has a roughed surface opposite to the substrate.

14. The light-emitting device of claim 12, further comprising an insulating layer, a reflective layer and a bonding layer, wherein the insulating layer is disposed on the light-emitting diode chip, the reflective layer is disposed on the insulating layer opposite to the light-emitting diode chip, and the bonding layer is disposed on the reflective layer opposite to the insulating layer for bonding the light-emitting diode chip to the substrate.

15. A light-emitting device comprising:
a light-emitting diode chip comprising a plurality of light-emitting diode units, and at least one electrical connecting structure, the light-emitting diode units being electrically connected with each other by the electrical connecting structure, each of the light-emitting diode units comprising a first semiconductor layer, a second semiconductor layer and an active layer; and
a sub-mount comprising al least one conductive layer disposed thereon;
wherein the light-emitting diode chip is bonded to and electrically connected to the sub-mount by the conductive layer.

16. The light-emitting device of claim 15, wherein the sub-mount comprises a lead frame, a mounting substrate, printed circuit board, and combinations thereof.

17. The light-emitting device of claim 15, further comprising a thermally conductive structure formed between the sub-mount and the light-emitting diode chip.

18. A method of making a light-emitting device comprising:
forming a light-emitting diode chip on a substrate, the light-emitting diode chip comprising a plurality of light-emitting diode units and a plurality of electrodes;
forming an insulation structure between the light-emitting diode units;
forming an electrical connection structure in the insulation structure for electrically connecting the light-emitting diode units;
applying an insulating layer to the electrical connection structure;
forming a plurality of channels in the substrate;
forming a conductive material within the channels for electrically connecting to the electrodes of the light-emitting diode chip; and
forming a plurality of external electrodes on the substrate for electrically connecting to the electrodes.

19. The method of claim 18, further comprising forming a reflective layer on the insulating layer opposite to the light-emitting diode chip, and forming a bonding layer on the reflective layer opposite to the insulating layer for bonding a carrier thereto.

20. The method of claim 18, further comprising removing the substrate.

21. The method of claim 18, further comprising forming a thermal conductive structure between the sub-mount and the light-emitting diode chip.
